(19) United States
(12) Patent Application Publication
(10) Pub. No.: US 2025/0365865 A1
(43) Pub. Date: Nov. 27, 2025

(54) SUBSTRATE STRUCTURE

(71) Applicant: UNIMICRON TECHNOLOGY CORP., Taoyuan City (TW)

(72) Inventors: Chun-Hung KUO, Taoyuan City (TW); Kuo-Ching CHEN, Taoyuan City (TW); Yu-Cheng HUANG, Taoyuan City (TW); Heng-Ming NIEN, Taoyuan City (TW); Yu-Hua CHEN, Taoyuan City (TW)

(73) Assignee: UNIMICRON TECHNOLOGY CORP., Taoyuan City (TW)

(21) Appl. No.: 18/783,752

(22) Filed: Jul. 25, 2024

(30) Foreign Application Priority Data
May 22, 2024 (TW) 113118931

(51) Int. Cl. H05K 1/11

(52) U.S. Cl. CPC H05K 1/115; H05K 2201/09509

(57) ABSTRACT

A substrate structure is provided. The substrate structure includes a substrate and a via. The substrate has a first side and a second side opposite to each other. The via is disposed in the substrate and penetrates the substrate along a first direction, wherein the via includes a first conductive component and a second conductive component. The first conductive component is adjacent to the first side of the substrate, wherein the first conductive component includes a first seed layer and a first conductive part. The second conductive component is adjacent to the second side of the substrate and electrically connected to the first conductive component, wherein a first contact interface is formed between the second conductive component and the first seed layer. The first contact interface extends along a second direction, and the second direction is different from the first direction.

### CROSS REFERENCE TO RELATED APPLICATIONS

This application claims priority of Taiwan Patent Application No. 113118931, filed on May 22, 2024, the entirety of which is incorporated by reference herein.

### BACKGROUND OF THE INVENTION

### Field of the Invention

The present disclosure relates to substrate structures, and, in particular, to a substrate structure having a via formed in stages by release materials.

### Description of the Related Art

In the substrate structures, electronic elements located on both sides of the substrate are usually connected through vias. For example, a through hole may be formed on the substrate through a drilling process such as laser drilling, mechanical drilling, etching, or a combination thereof. Then, a via may be formed by disposing a seed layer and electroplating conductive material in the through hole. However, the process of plating conductive material into the through hole from both sides is not easy to control. In some cases, the formed via may have unintended voids, especially at the center of the via. Alternatively, in some cases, the conductive material in the via may also dimple inward, resulting in poor electrical properties of the product. Therefore, although existing substrate structures have largely met their intended purposes, they do not meet requirements in all respects. Therefore, there is still a need to develop new substrate structures.

### BRIEF SUMMARY OF THE INVENTION

In some embodiments, a substrate structure is provided. The substrate structure includes a substrate and a via. The substrate has a first side and a second side opposite to each other. The via is disposed in the substrate and penetrates the substrate along a first direction, wherein the via includes a first conductive component and a second conductive component. The first conductive component is adjacent to the first side of the substrate, wherein the first conductive component includes a first seed layer and a first conductive portion. The second conductive component is adjacent to the second side of the substrate and electrically connected to the first conductive component, wherein a first contact interface is formed between the second conductive component and the first seed layer. The first contact interface extends along a second direction, and the second direction is different from the first direction.

In some embodiments, the first conductive component has a first sidewall, the second conductive component has a second sidewall, and the first sidewall and the second sidewall forms a continuous sidewall.

In some embodiments, the second conductive component includes a second seed layer and a second conductive part, and the second seed layer is in direct contact with the first seed layer to form the first contact interface.

In some embodiments, the first conductive part and the second conductive part are separated from each other by the first seed layer and the second seed layer.

In some embodiments, the second conductive component includes a second conductive part, and the second conductive part is in direct contact with the first seed layer to form the first contact interface.

In some embodiments, the first conductive part and the second conductive part are separated by the first seed layer.

In some embodiments, the first conductive part is in direct contact with the second conductive part to form a second contact interface.

In some embodiments, the second conductive component includes a second seed layer and a second conductive part, and the second seed layer is in direct contact with the first seed layer to form the first contact interface, and the second seed layer is in direct contact with the first conductive part to form a second contact interface.

In some embodiments, the via further includes a third conductive component, the third conductive component is disposed in the substrate and penetrates the substrate along the first direction, and the third conductive component surrounds the first conductive component and the second conductive component.

In some embodiments, the second conductive component includes a second conductive part, and the second conductive part is in direct contact with the first seed layer to form the first contact interface.

In some embodiments, the first conductive part and the second conductive part are separated by the first seed layer.

In some embodiments, the angle between the first direction and the second direction is greater than 0 degrees and less than 180 degrees.

In some embodiments, the first direction and the second direction are perpendicular to each other.

In some embodiments, the first conductive component has a first height, the second conductive component has a second height, and the ratio of the first height to the second height is between 1:2 and 2:1.

In some embodiments, the first height is the same as the second height.

In some embodiments, the first conductive component has a first width, the second conductive component has a second width, and the first width is the same as the second width.

In some embodiments, the first contact interface has a curvature greater than 0.

In some embodiments, the first conductive component has a first width, and the second conductive component has a second width, wherein the first width decrease from one side adjacent to the first surface toward one side away from the first surface, or the second width decreases from one side adjacent to the second surface toward one side away from the second surface.

In some embodiments, the via further includes a first conductive protrusion and a second conductive protrusion, wherein the first conductive protrusion is disposed on the first conductive component and protrudes from the first surface of the substrate, and the second conductive protrusion is disposed on the second conductive component and protrudes from the second surface of the substrate.

In some embodiments, the first conductive component has a first width, the second conductive component has a second width, the first conductive protrusion has a third width, and the second conductive protrusion has a fourth width, wherein the third width is greater than the first width, and the fourth width is greater than the second width.

The device of the present disclosure may be applied in a variety of electronic devices. In order to make the features and advantages of the present disclosure more comprehensible, various embodiments are specially cited hereinafter, together with the accompanying drawings, to be described in detail as follows.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIGS. 1 and 2 are schematic cross-sectional views of the substrate structure at different steps in the forming method according to some embodiments of the present disclosure.

FIGS. 3A, 3B are schematic cross-sectional views of the substrate structure at different steps in the forming method according to some embodiments of the present disclosure.

FIGS. 4 to 10 are schematic cross-sectional views of the substrate structure at different steps in the forming method according to some embodiments of the present disclosure.

FIG. 11 is an enlarged schematic diagram of the area C in FIG. 10.

FIGS. 12A and 12B are respectively schematic cross-sectional views of the substrate structure according to other embodiments of the present disclosure.

FIGS. 13 and 14 are schematic cross-sectional views of the substrate structure at different steps in the forming method according to further embodiments of the present disclosure.

FIGS. 15 and 16 are schematic cross-sectional views of the substrate structure at different steps in the forming method according to further embodiments of the present disclosure.

FIG. 17 is a schematic cross-sectional view of the substrate structure at different steps in the forming method according to further embodiments of the present disclosure.

FIG. 18 is an enlarged schematic view of the area D in FIG. 17.

FIGS. 19 to 22 are schematic cross-sectional views of the substrate structure at different steps in the forming method according to further embodiments of the present disclosure.

FIG. 23 is an enlarged schematic diagram of the area E in FIG. 22.

### DETAILED DESCRIPTION OF THE INVENTION

The devices of various embodiments of the present disclosure will be described in detail below. It should be understood that the following description provides many different embodiments for implementing various aspects of some embodiments of the present disclosure. The specific elements and arrangements described below are merely to clearly describe some embodiments of the present disclosure. Of course, these are only used as examples rather than limitations of the present disclosure. Furthermore, similar or corresponding reference numerals may be used in different embodiments to designate similar or corresponding elements in order to clearly describe the present disclosure. However, the use of these similar or corresponding reference numerals is only for the purpose of simply and clearly description of some embodiments of the present disclosure, and does not imply any correlation between the different embodiments or structures discussed.

In addition, it should be understood that ordinal numbers such as “first”, “second”, and the like used in the description and claims are used to modify elements and are not intended to imply and represent the element(s) have any previous ordinal numbers, and do not represent the order of a certain element and another element, or the order of the manufacturing method, and the use of these ordinal numbers is only used to clearly distinguished an element with a certain name and another element with the same name. The claims and the specification may not use the same terms, for example, a first element in the specification may be a second element in the claim.

In some embodiments of the present disclosure, terms related to bonding and connection, such as “connect”, “interconnect”, “bond”, and the like, unless otherwise defined, may refer to two structures in direct contact, or may also refer to two structures not in direct contact, that is there is another structure disposed between the two structures. Moreover, the terms related to bonding and connection may also include embodiments in which both structures are movable, or both structures are fixed. Furthermore, the terms “electrically connected” or “electrically coupled” include any direct and indirect means of electrical connection.

Herein, the terms “approximately”, “about”, and “substantially” generally mean within 10%, within 5%, within 3%, within 2%, within 1%, or within 0.5% of a given value or range. The given value is an approximate value, that is, “approximately”, “about”, and “substantially” may still be implied without the specific description of “approximately”, “about”, and “substantially”. The phrase “a range between a first value and a second value” means that the range includes the first value, the second value, and other values in between. Furthermore, any two values or directions used for comparison may have certain tolerance. If the first value is equal to the second value, it implies that there may be a tolerance within about 10%, within 5%, within 3%, within 2%, within 1%, or within 0.5% between the first value and the second value. If the first direction is perpendicular to the second direction, the angle between the first direction and the second direction may be between 80 degrees and 100 degrees. If the first direction is parallel to the second direction, the angle between the first direction and the second direction may be between 0 degrees and 10 degrees.

It should be understood that, in the following embodiments, features in several different embodiments may be replaced, recombined, and bonded to complete other embodiments without departing from the spirit of the present disclosure. The features of the various embodiments may be used in any combination as long as they do not violate the spirit of the present disclosure or conflict with each other.

Unless otherwise defined, all terms (including technical and scientific terms) used herein have the same meaning as commonly understood by a person of ordinary skill in the art. It is understood that these terms, such as those defined in commonly used dictionaries, should be interpreted as having meanings consistent with the relevant art and the background or context of the present disclosure, and should not be interpreted in an idealized or overly formal manner, unless otherwise defined in the embodiments of the present disclosure.

In order to obtain vias with a complete structure and good electrical properties in the substrate structure, the electroplating process and formula have been continuously improved. However, up to now, the via formed by filling the conductive material at one time still has the problem of pores (or voids) or collapse. In some aspects where the via is a straight via, the above problem is even more significant.

To this end, the present disclosure provides a substrate structure, and the forming method thereof generally includes the following steps. First, a release material is filled into the through hole to fill one end (e.g., the first end) of the through hole. Next, using the release material as a temporary carrier, a part of the via (e.g., the lower portion) is first formed in the other end (e.g., the second end) of the through hole. Finally, the release material is removed and the remaining part (e.g., the upper portion) of the via is formed in the first end of the via. In other words, the present disclosure effectively avoids the problem of voids or collapse in the center of the via by forming the upper and lower portions of the via in stages. In order to make the technical features of the present disclosure clearer and easier to understand, some embodiments of the present disclosure is described below with reference to the drawings.

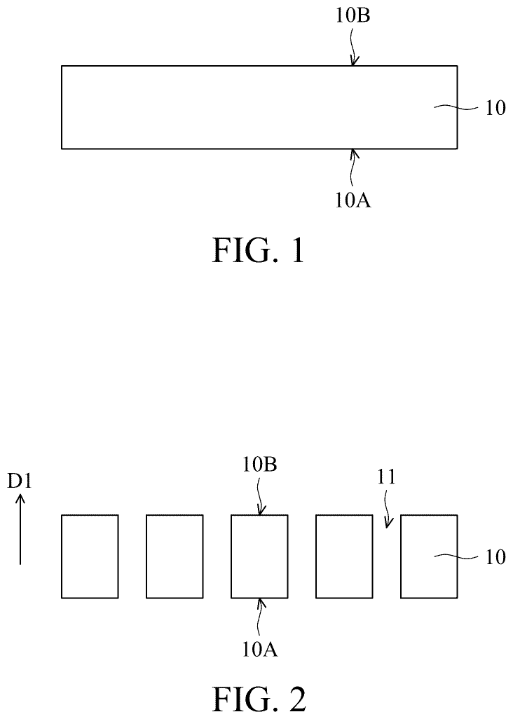

FIGS. 1 to 10 are schematic cross-sectional views of the substrate structure at different steps in the forming method according to some embodiments of the present disclosure. It should be understood that, for clarity of explanation, some components of the substrate structure are omitted in the drawings, and only some components are schematically illustrated. In some embodiments, additional components may be added to the substrate structure described below. In other embodiments, some components of the substrate structure described below may be replaced or omitted. It should be understood that in some embodiments, additional operational steps may be provided before, during, and/or after the method of forming the substrate structure. In some embodiments, some of the steps described may be replaced or omitted, and the order of some of the steps described is interchangeable.

As shown in FIG. 1, the substrate 10 is provided, and the substrate 10 has the first surface 10A and the second surface 10B opposite to each other. In some embodiments, the substrate 10 may include a core layer, and the core layer may be an organic core layer, an inorganic core layer, or a composite core layer. For example, the material of the core layer may be or include epoxy resin, polyimide (PI), phenol formaldehyde resins (PF), bismaleimide triazine resin (BT), glass fiber, carbon fiber, epoxy glass cloth, other suitable materials, or a combination thereof, but the present disclosure is not limited thereto. In some embodiments, the substrate 10 may be a single-layer board or a multi-layer board.

As shown in FIG. 2, following the above steps, the through hole 11 is formed in the substrate 10, and the through hole 11 penetrates the substrate 10 along the first direction D1. In some embodiments, the through hole 11 may be formed by a drilling process or an etching process, but the present disclosure is not limited thereto. For example, the drilling process may be or include laser drilling, mechanical drilling, other suitable drilling processes, or a combination thereof, but the present disclosure is not limited thereto. Alternatively, the etching process may be or may include dry etching (e.g., reactive-ion etching (RIE)), wet etching, other suitable etching methods, or a combination thereof, but the present disclosure is not limited thereto.

It should be noted that although the steps of forming four vertical through holes on the substrate 10 are shown in the figures, they are only used to make the present disclosure clearer and easier to understand but are not intended to limit the present disclosure. In other words, in other embodiments, the size, shape, proportion, and other parameters of the through hole 11 may be determined according to actual conditions. For example, the through hole 11 may also be a funnel-shaped through hole, an hourglass-shaped through hole, a pear-shaped through hole, a through hole with arc-shaped sidewalls, or other suitable through holes, but the present disclosure is not limited thereto.

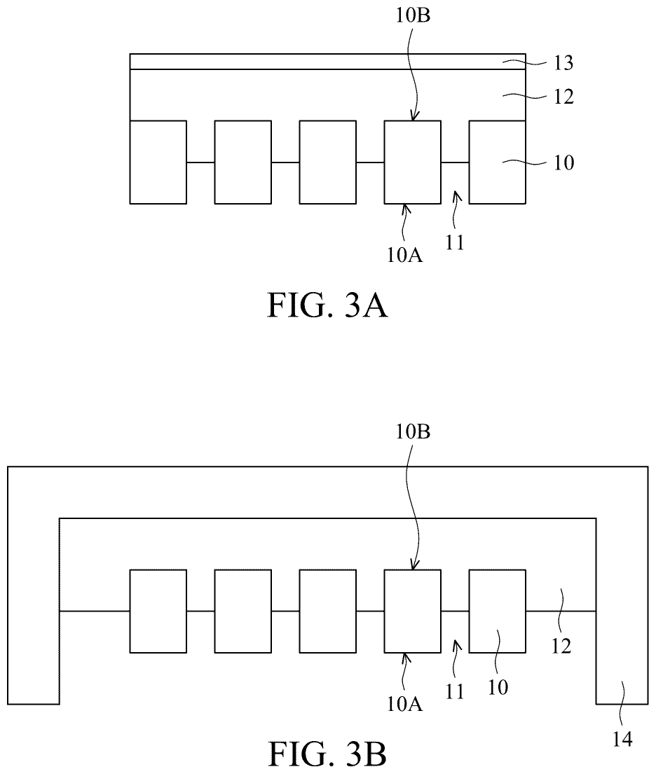

As shown in FIG. 3A, following the above steps, the release material 12 is disposed on the second surface 10B of the substrate 10, wherein the release material 12 fills a part of the through hole 11 from the second surface 10B toward the first surface 10A of the substrate 10. By filling a part of the through hole 11 with the release material 12, the release material 12 located in the through hole 11 may be used as a temporary carrier to facilitate the subsequent placement of the seed layer material in the through hole 11 (e.g., the first seed layer material 15 described below) and the conductive material (e.g., the first conductive material 16 described below).

In some embodiments, the release material 12 may fill 1/3 to 2/3 of the total volume of the through hole 11, but the present disclosure is not limited thereto. For example, the release material 12 may fill 20%, 25%, 30%, 33%, 50%, 67%, 70%, 75%, 80%, or any value or range between the above values of the total volume of the through hole 11. In some cases, when the release material 12 fills the through hole 11 with less than 20% of the total volume of the through hole 11, there may be too much remaining space in the lower end of the through hole 11 (the end adjacent to the first surface 10A). As a result, when the conductive material is subsequently filled in the through hole 11 along the direction of the first surface 10A toward the second surface 10B of the substrate 10, the remaining space of the through hole 11 may be too large (or too deep), thereby producing unexpected pores in the through hole. On the contrary, when the release material 12 fills the through hole 11 with higher than 80% of the total volume of the through hole 11, after the release material 12 is removed, the remaining space in the upper end of the through hole 11 (the end adjacent to the second surface 10B) may be too much. As a result, when the conductive material is subsequently filled in the through hole 11 along the direction of the second surface 10B toward the first surface 10A of the substrate 10, the remaining space of the through hole 11 may be too large (or too deep), thereby producing unexpected pores in the through hole. In actual applications, the degree to which the release material 12 fills the through hole 11 may be determined based on the depth (or height) of the through hole 11, the physical properties (e.g., viscosity) of the release material 12, other parameters, or a combination thereof, and is not limited to the proportions stated above.

In some embodiments, the release material 12 may be or may include a solid release material (e.g., dry film), a liquid release material (e.g., colloid), other suitable release materials, or a combination thereof. For example, taking FIG. 3A as an example, it shows the application process of the solid release material 12. In these embodiments, the release material 12 is attached to the carrier film 13 such as polyethylene terephthalate (PET), and the release material 12 is pressed onto the second surface of the substrate 10 to fill with the through holes 11 by a device such as a vacuum laminator. Alternatively, taking FIG. 3B as an example, it shows the application process of the liquid release material 12. In these embodiments, the release material 12 is accommodated in the mold 14 and penetrates into the through hole 11 from the second surface 10B of the substrate 10 through the communication tube principle. Then, the liquid release material 12 may be cured by illumination (e.g., ultraviolet light), heating, other suitable methods, or a combination thereof. After the release material 12 is cured, the mold 14 may be removed. It should be noted that although two types of the release material 12 are described above, the present disclosure is not limited thereto. In practical applications, the application method may be selected according to the characteristics or types of the release material 12.

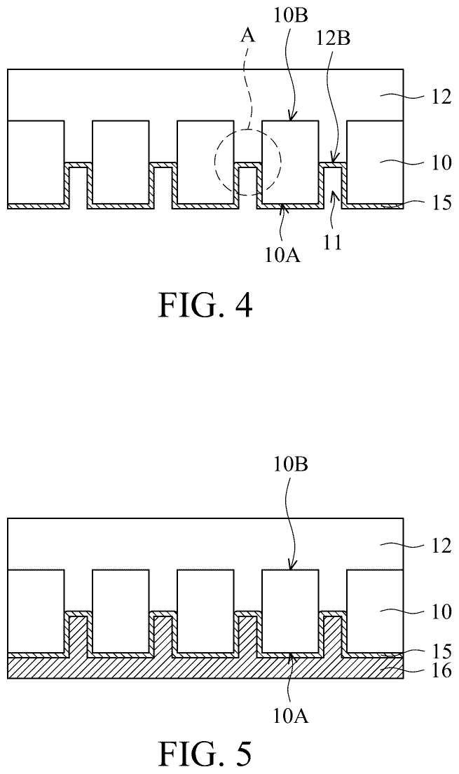

As shown in FIG. 4, following the above steps, the first seed layer material 15 is disposed on the first surface 10A of the substrate 10 and in one end of the through hole 11 adjacent to the first surface 10A. In some embodiments, a chemical vapor deposition (CVD) process, a physical vapor deposition (PVD) process, an electroless plating, other suitable deposition processes, or a combination thereof may be used to from the first seed layer material 15 into the through hole 11. It should be noted that since the end of the through hole 11 adjacent to the second surface 10B has been filled with the release material 12, the first seed layer material 15 grows along the inner sidewall of the substrate 10 and the bottom surface 12B of the release material 12. In other words, the release material 12 in the through hole 11 may serve as a temporary carrier so that the first seed layer material 15 forms a bridge-like structure in the through hole 11 (i.e., the area A in FIG. 4). In some embodiments, the first seed layer material 15 may be or may include copper (Cu), but the present disclosure is not limited thereto.

As shown in FIG. 5, following the above steps, the first conductive material 16 is plated on the first seed layer material 15. For example, the plating process may be or include electroplating, electroless plating, other suitable plating processes, or a combination thereof, but the present disclosure is not limited thereto. In some embodiments, the first conductive material 16 may be or may include aluminum (Al), copper, alloys thereof, or compounds thereof, but the present disclosure is not limited thereto. For example, the copper alloy or compound may be or include brass, phosphor bronze, beryllium copper, or oxygen-free copper, but the present disclosure is not limited thereto. In some embodiments, the first conductive material 16 may be similar or the same as the first seed layer material 15, but the present disclosure is not limited thereto.

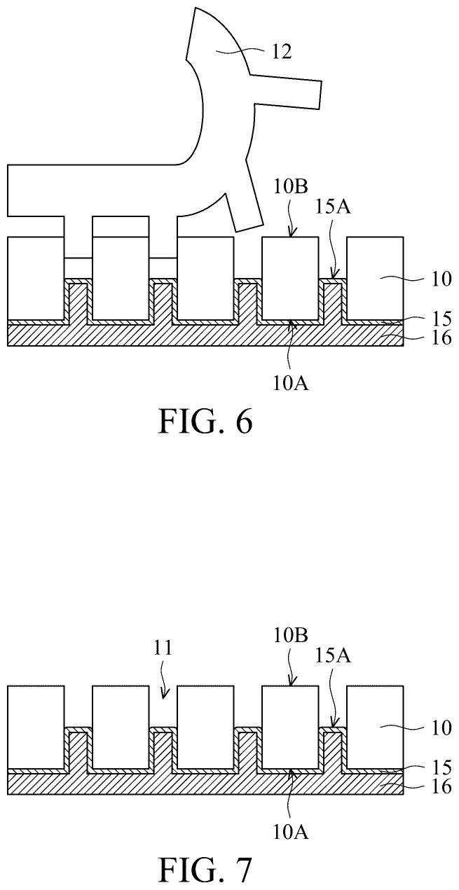

As shown in FIG. 6, following the above steps, the release material 12 is removed. In some embodiments, the release material 12 may be removed in physically way or chemically way. For example, the physical way may include direct tearing, and the chemical way may include solvent stripping, but the present disclosure is not limited thereto. In some embodiments, the residue of the release material 12 in the through hole 11 may be further removed by plasma cleaning, desmearing, another suitable method, or a combination thereof. As shown in FIG. 7, after the release material 12 is removed, the top surface 15A of the first seed layer material 15 is exposed from the through hole 11, and the second surface 10B of the substrate 10 is exposed.

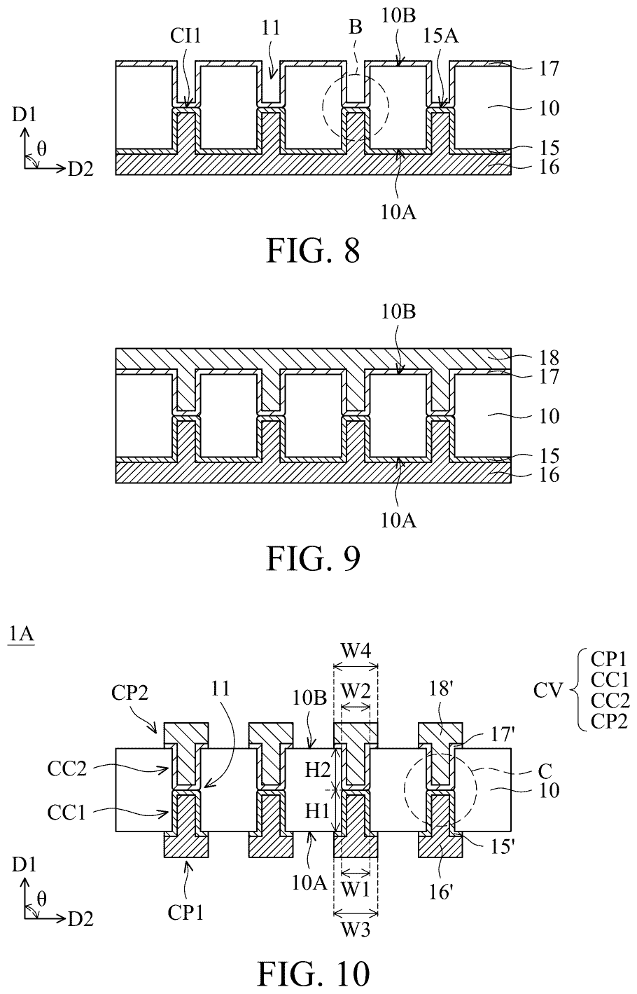

As shown in FIG. 8, following the above steps, the second seed layer material 17 is disposed on the second surface 10B of the substrate 10 and in one end of the through hole 11 adjacent to the second surface 10B. In some embodiments, the second seed layer material 17 may be formed in the through hole 11 by a chemical vapor deposition process, a physical vapor deposition process, other suitable deposition processes, or a combination thereof. It should be noted that since the end of the through hole 11 adjacent to the first surface 10A has been filled with the first seed layer material 15 and the first conductive material 16, the second seed layer material 17 grows along the inner sidewalls of the substrate 10 and the top surface 15A of the first seed layer material 15. In other words, the first seed layer material 15 in the through hole 11 may serve as a carrier to facilitate the second seed layer material 17 to form a bridge-like structure in the through hole 11 (i.e., the area B in FIG. 8). In some embodiments, the second seed layer material 17 may be or may include copper (Cu), but the present disclosure is not limited thereto. In some embodiments, the second seed layer material 17 may be similar or the same as the first seed layer material 15, but the present disclosure is not limited thereto.

In some embodiments, the first contact interface CI1 is formed between the second seed layer material 17 and the first seed layer material 15, and the first contact interface CI1 extends along the second direction D2. In some embodiments, the second direction D2 is different from the first direction D1, and the angle θ between the first direction D1 and the second direction D2 is greater than 0 degrees and less than 180 degrees. For example, when the first direction D1 and the second direction D2 are perpendicular to each other (i.e., the angle θ is 90 degrees), the extending direction of the first contact interface CI1 (i.e., the second direction D2) and the extending direction of the through hole 11 (i.e., the first direction D1) are perpendicular to each other. In this case, the first contact interface CI1 may be a horizontal interface, but the present disclosure is not limited thereto. In some embodiments, when the release material 12 in FIG. 3A, FIG. 3B, or FIG. 4 has an arc-shaped or irregular bottom surface 12B in the through hole 11, the bottom surface of the subsequent formed second seed layer material 17 and the top surface of the first seed layer material 15 may also present an arc shape or an irregular shape. In this way, the first contact interface CI1 between the second seed layer material 17 and the first seed layer material 15 may have an arc shape or an irregular shape. In some embodiments, the first contact interface CI1 may show an obvious boundary when observed with the naked eye or under an optical microscope, but the present disclosure is not limited thereto.

As shown in FIG. 9, following the above steps, the second conductive material 18 is plated on the second seed layer material 17. In some embodiments, the second conductive material 18 may be or include aluminum, copper, alloys or compounds thereof, but the present disclosure is not limited thereto. In some embodiments, the second conductive material 18 may be similar or the same as the second seed layer material 17, but the present disclosure is not limited thereto. In some embodiments, the second conductive material 18 may be similar or the same as the first conductive material 16, but the present disclosure is not limited thereto.

As shown in FIG. 10, following the above steps, a part of the first seed layer material 15 and a part of the first conductive material 16 are removed to form the first seed layer 15′ and the first conductive part 16′. Among them, the first seed layer 15′ and the first conductive part 16′ in the through hole 11 may be collectively referred to as the first conductive component CC1, and the first seed layer 15′ and the first conductive part 16′ outside the through hole 11 may be collectively referred to as first conductive protrusion CP1. In some embodiments, the first seed layer material 15 and the first conductive material 16 may be patterned through a photolithography process and an etching process to form the first conductive component CC1 and the first conductive protrusion CP1, but the present disclosure is not limited thereto. In some embodiments, the lithography process may include photoresist coating (e.g., spin-on coating), soft baking, mask aligning, exposure, post-exposure baking, photoresist developing, rinsing, drying (e.g., spin-drying and/or hard baking), other suitable lithography techniques, and/or a combination thereof.

In addition, a part of the second seed layer material 17 and a part of the second conductive material 18 are removed to form the second seed layer 17′ and the second conductive part 18′. Among them, the second seed layer 17′ and the second conductive part 18′ in the through hole 11 may be collectively referred to as the second conductive component CC2, and the second seed layer 17′ and the second conductive part 18′ outside the through hole 11 may be collectively referred to as the second conductive protrusion CP2. In some embodiments, the second seed layer material 17 and the second conductive material 18 may be patterned through a photolithography process and an etching process to form the second conductive component CC2 and the second conductive protrusion CP2, but the present disclosure is not limited thereto. In some embodiments, the first conductive component CC1, the first conductive protrusion CP1, the second conductive component CC2, and the second conductive protrusion CP2 may be collectively referred to as a via CV, and the via CV is used to realize the electrical connections on both sides of the substrate 10 (i.e., the first surface 10A and the second surface 10B).

Based on the above, in these embodiments, the substrate structure 1A is provided. As shown in FIG. 10, the substrate structure 1A includes the substrate 10 and the via CV. The substrate 10 has the first surface 10A and the second surface 10B opposite to each other. The via CV is disposed in the substrate 10 and penetrates the substrate 10 along the first direction D1, and the via CV includes the first conductive component CC1, the first conductive protrusion CP1, the second conductive component CC2, and the second conductive protrusion CP2.

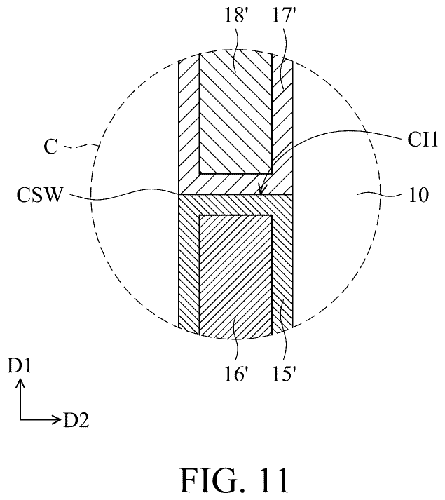

The first conductive component CC1 is adjacent to the first surface 10A of the substrate 10 and is electrically connected to the first conductive protrusion CP1, and the second conductive component CC2 is adjacent to the second surface 10B of the substrate 10 and is electrically connected to the first conductive component CC1 and the second conductive protrusion CP2. FIG. 11 is an enlarged schematic diagram of the area C of FIG. 10. As shown in FIG. 11, the first seed layer 15′ of the first conductive component CC1 is in direct contact with the second seed layer 17′ of the second conductive component CC2 to form the first contact interface CI1, wherein the first contact interface CI1 extends along the second direction D2 which is different from the first direction D1. In addition, the first conductive part 16′ of the first conductive component CC1 and the second conductive part 18′ of the second conductive component CC2 are separated from each other by the first seed layer 15′ and the second seed layer 17′.

As shown in FIG. 10, in some embodiments, depending on the extent to which the release material 12 is filled into the through hole 11, the first conductive component CC1 may have the first height H1 and the second conductive component CC2 may have the second height H2. In some embodiments, the ratio of the first height H1 to the second height H2 is between 1:2 and 2:1. For example, the first height H1 may be the same as the second height H2 (i.e., H1=H2). In some embodiments, depending on the size (e.g., width) of the via 11, the first conductive component CC1 may have the first width W1 and the second conductive component CC2 may have the second width W2. For example, the first width W1 may be the same as the second width W2 (i.e., W1=W2).

As shown in FIG. 10, the first conductive protrusion CP1 is disposed on the first conductive component CC1 and protrudes from the first surface 10A of the substrate 10, and the second conductive protrusion CP2 is disposed on the second conductive component CC2 and protrudes from the second surface 10B of the substrate 10. In some embodiments, depending on the size of the electronic component (not shown) to be connected, the first conductive protrusion CP1 has the third width W3 and the second conductive protrusion CP2 has the fourth width W4. In some embodiments, the third width W3 and the fourth width W4 are respectively larger than the first width W1 and the second width W2 (i.e., W3>W1, and W4>W2).

As shown in FIG. 11, in some embodiments, the first conductive component CC1 has the first sidewall SW1, and the second conductive component CC2 has the second sidewall SW2. Since the first conductive component CC1 and the second conductive component CC2 of the present disclosure are sequentially formed in the same through hole 11, the first sidewall SW1 of the first conductive component CC1 and the second sidewall SW2 of the second conductive component CC2 are each aligned with the inner sidewall of the substrate 10, and the first sidewall SW1 of the first conductive component CC1 and the second sidewall SW2 of the second conductive component CC2 form the continuous sidewall CSW. Compared with the method of separately arranging blind holes and stacking them to form vias, the via CV of the present disclosure does not have the problem of steps or gaps due to inaccurate alignment.

In the above, according to some embodiments of the disclosure, a possible implementation of the substrate structure prepared by release materials has been provided, but the present disclosure is not limited thereto. Therefore, in the following, other implementation aspects of the substrate structure according to different embodiments of the present disclosure are provided for reference.

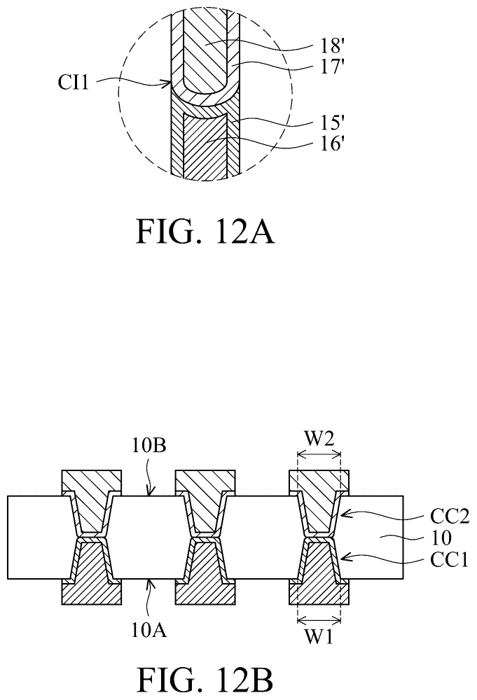

FIGS. 12A and 12B are respectively schematic cross-sectional views of the substrate structure according to other embodiments of the present disclosure. As shown in FIG. 12A, in some embodiments, when the release material 12 in FIG. 3A, FIG. 3B, or FIG. 4 has the bottom surface 12B with a curvature greater than 0 in the through hole 11, the bottom surface of the subsequently formed second seed layer 17′ and the top surface of the subsequently formed first seed layer 15′ may also have a shape with a curvature greater than 0. In this way, the first contact interface CI1 between the second seed layer 17′ and the first seed layer 15′ may have a curvature greater than 0. As shown in FIG. 12B, in some embodiments, when the through hole 11 formed in FIG. 2 is an hourglass-shaped through hole (e.g., formed by etching), the first width W1 of the subsequently formed first conductive component CC1 decreases from the side adjacent to the first surface 10A toward the side away from the first surface 10A, or the second width W2 of the subsequently formed second conductive component CC2 decreases from the side adjacent to the second surface 10B toward the side away from the second surface 10B. In some embodiments, the degree of decrement of the first width W1 may be greater than, equal to, or less than the degree of decrement of the second width W2.

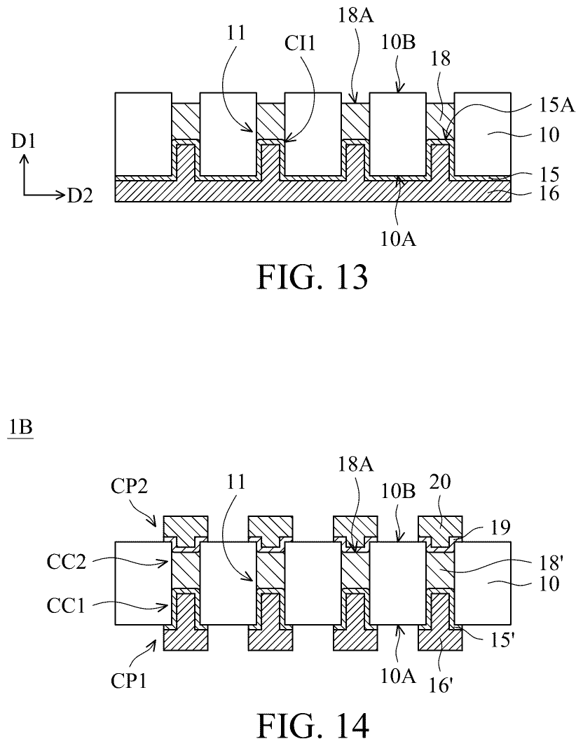

FIGS. 13 and 14 are schematic cross-sectional views of the substrate structure at different steps in the forming method according to further embodiments of the present disclosure. Specifically, FIG. 13 follows the steps of FIG. 7, wherein all previous steps may be described with reference to FIGS. 1 to 7 and therefore are omitted. Compared with the substrate structure 1A of FIGS. 1 to 10, the contact interface between the first conductive component CC1 and the second conductive component CC2 of the substrate structure 1B of FIGS. 13 and 14 is adjusted. The detailed descriptions are shown hereafter.

As shown in FIG. 13, following the steps described in FIG. 7, the second seed layer material is not provided, so the second conductive material 18 is directly provided in one end of the through hole 11 adjacent to the second surface 10B. In some embodiments, the second conductive material 18 may be provided through a plating process. It should be noted that since the end of the through hole 11 adjacent to the first surface 10A has been filled with the first seed layer material 15 and the first conductive material 16, the second conductive material 18 is stacked along the top surface 15A of the first seed layer material 15 toward the second surface 10B of the substrate 10. In other words, the first seed layer material 15 in the through hole 11 may serve as a carrier so that the second conductive material 18 may be filled into the through hole 11. It should be noted that, in order to facilitate the subsequent formation of the second conductive protrusion CP2, the top surface 18A of the second conductive material 18 may be made lower than the second surface 10B of the substrate 10. In some embodiments, the first contact interface CI1 is formed between the second conductive material 18 and the first seed layer material 15, and the first contact interface CI1 extends along the second direction D2.

As shown in FIG. 14, following the above steps, a part of the first seed layer material 15 and a part of the first conductive material 16 are removed to form the first seed layer 15′ and the first conductive part 16′. Among them, the first seed layer 15′ and the first conductive part 16′ in the through hole 11 may be collectively referred to as the first conductive component CC1, and the first seed layer 15′ and the first conductive part 16′ outside the through hole 11 may be collectively referred to as the first conductive protrusion CP1.

On the other side, the second seed layer material is provided on the top surface 18A of the second conductive material 18 (also referred to as the second conductive part 18′) and the second surface 10B of the substrate 10, and the third conductive material is plated on the second seed layer material. Then, a part of the second seed layer material and a part of the third conductive material are removed to form the second seed layer 19 and the third conductive part 20. Among them, the second conductive part 18′ and the second seed layer 19 in the through hole 11 may be collectively referred to as the second conductive component CC2, and the second seed layer 19 and the third conductive part 20 outside the through hole 11 may be collectively referred to as second conductive protrusions CP2.

It should be noted that in these embodiments, the second seed layer 19 may be disposed on the side of the second conductive material 18 (or the second conductive part 18′) away from the first seed layer 15′ to form the second conductive protrusion CP2, wherein the second conductive protrusion CP2 protrudes from the substrate 10 and has a width larger than that of the substrate 10 on the second surface 10B of the substrate 10. However, the present disclosure is not limited thereto. In other embodiments, if the width of the second conductive protrusion CP2 to be formed is equal to or smaller than the through hole 11 (i.e., the projection on the horizontal plane does not overlap with the substrate 10), the disposing step of the second seed layer material may be omitted, and the second conductive material is grown to protrude from the second surface 10B of the substrate 10. On the other hand, in these embodiments, there is no seed layer between the second conductive part 18′ and the sidewall of the substrate 10, and the second conductive part 18′ is in direct contact with the sidewall of the substrate 10. In addition, the second conductive part 18′ is in direct contact with the first seed layer 15′ to form the first contact interface CI1, and the first conductive part 16′ and the second conductive part 18′ are separated by the first seed layer 15′.

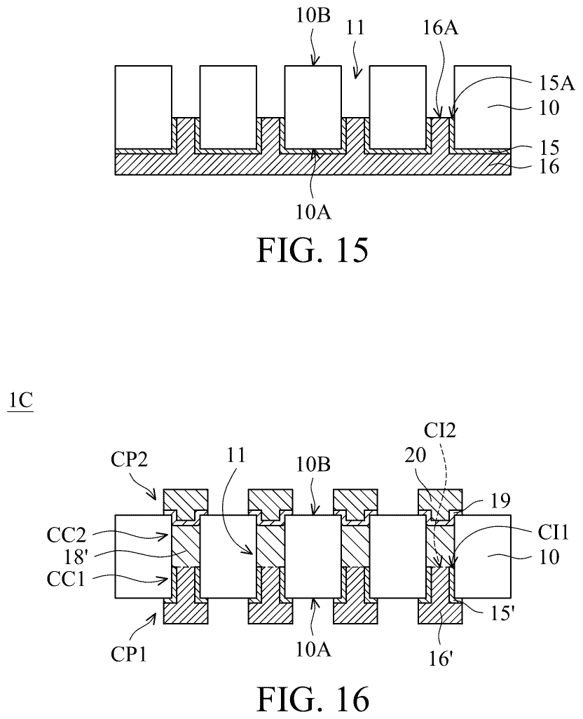

FIGS. 15 and 16 are schematic cross-sectional views of the substrate structure at different steps in the forming method according to further embodiments of the present disclosure. Specifically, FIG. 15 follows the steps of FIG. 7, wherein all previous steps may be described with reference to FIGS. 1 to 7 and therefore are omitted. Compared with the substrate structure 1B of FIGS. 13 and 14, the contact interface between the first conductive component CC1 and the second conductive component CC2 of the substrate structure 1C of FIGS. 15 and 16 is adjusted. The detailed descriptions are shown hereafter.

As shown in FIG. 15, following the steps described in FIG. 7, a part of the first seed layer material 15 is removed, so that the top surface 16A of the first conductive material 16 and the top surface 15A of the first seed layer material 15 are exposed. As shown in FIG. 16, the steps described in FIGS. 13 and 14 are subsequently performed to obtain the substrate structure 1C.

As shown in FIG. 16, the difference from the substrate structure 1B is that a part of the first seed layer material 15 of the substrate structure 1C is removed, so that the first contact interface CI1 is formed between the second conductive part 18′ and the first seed layer material 15, and the second contact interface CI2 is formed between the second conductive part 18′ and the first conductive part 16′. Specifically, there is no seed layer between the second conductive part 18′ and the inner sidewall of the substrate 10, and the second conductive part 18′ is in direct contact with the inner sidewall of the substrate 10. In addition, the second conductive part 18′ is in direct contact with the first seed layer 15′ to form the first contact interface CI1, and the second conductive part 18′ is in direct contact with the first conductive part 16′ to form the second contact interface CI2.

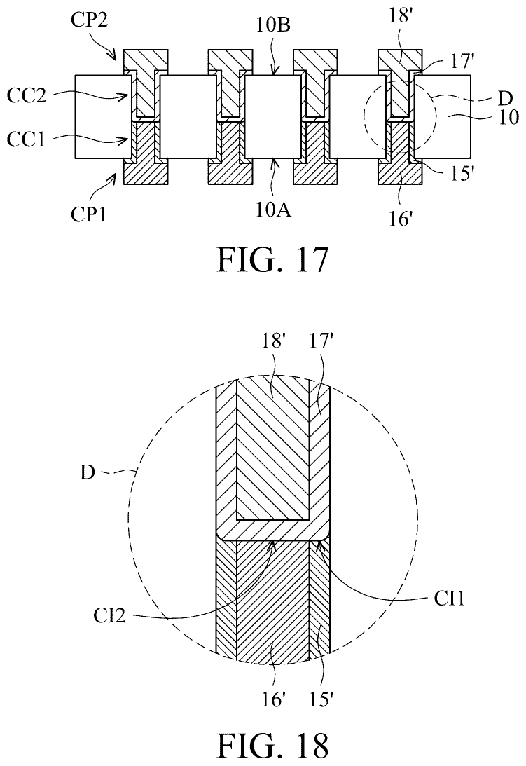

FIG. 17 is a schematic cross-sectional view of the substrate structure at different steps in the forming method according to further embodiments of the present disclosure, and FIG. 18 is an enlarged schematic view of the area D in FIG. 17. Specifically, the substrate structure 1D of FIG. 17 is obtained by sequentially executing the steps described in FIGS. 1 to 7, the steps described in FIG. 15, and the steps described in FIGS. 8 to 10. Compared with the substrate structure 1A of FIGS. 1 to 10, the contact interface between the first conductive component CC1 and the second conductive component CC2 of the substrate structure 1D of FIGS. 17 and 18 is adjusted. The detailed descriptions are shown hereafter.

As shown in FIGS. 17 and 18, the difference from the substrate structure 1A is that a part of the first seed layer material 15 of the substrate structure 1D is removed, so that the second seed layer 17′ is in contact with the first seed layer, so that the first contact interface CI1 is formed between the second seed layer 17′ and the first conductive part 16′, and the second contact interface CI2 is formed between the second seed layer 17′ and the first conductive part 16′.

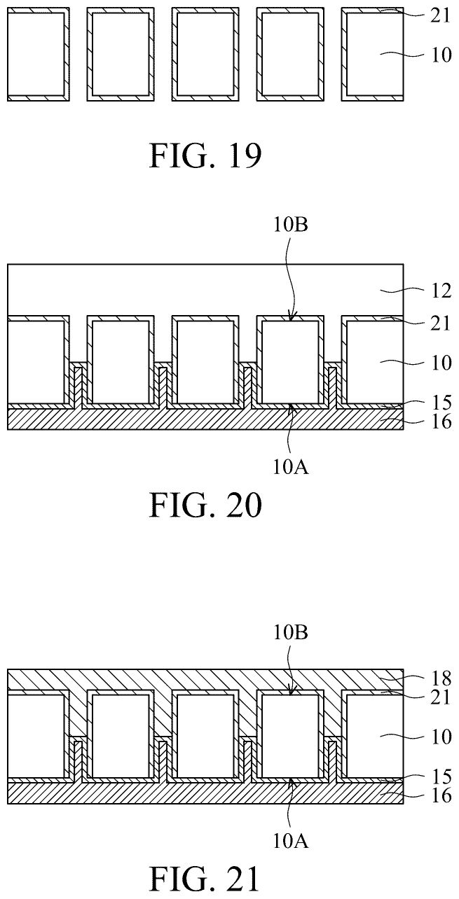

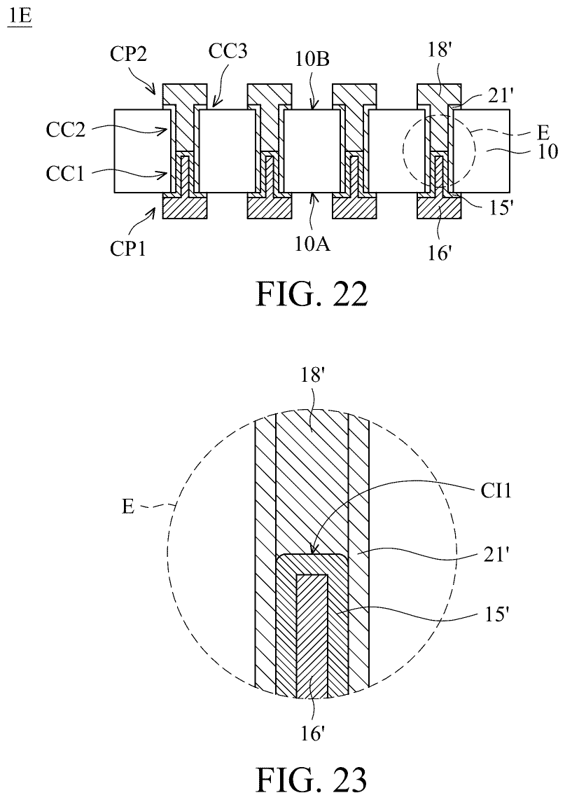

FIGS. 19 to 22 are schematic cross-sectional views of the substrate structure at different steps in the forming method according to further embodiments of the present disclosure, and FIG. 23 is an enlarged schematic diagram of the area E of FIG. 22. Compared with the substrate structure 1A of FIGS. 1 to 10, the contact interface between the first conductive component CC1 and the second conductive component CC2 of the substrate structure 1E of FIGS. 19 to 23 is adjusted. The detailed descriptions are shown hereafter.

As shown in FIG. 19, the first substrate 10 is provided, and the third seed layer material 21 is provided on the first substrate 10. In some embodiments, the third seed layer material 21 may be or may include copper, but the present disclosure is not limited thereto. As shown in FIG. 20, the release material 12 is provided on the second surface 10B of the substrate 10, the first seed layer material 15 is provided on the first surface 10A of the substrate 10 and in one end of the through hole 11 adjacent to the first surface 10A, and the first conductive material 16 is plated on the first seed layer material 15. As shown in FIG. 21, the release material 12 is removed to expose the third seed layer material 21, and the second conductive material 18 is plated on the third seed layer material 21.

As shown in FIG. 22, a part of the first seed layer material 15, a part of the first conductive material 16, a part of the second conductive material 18, and a part of the third seed layer material 21 are removed to form the first seed layer 15′, the first conductive part 16′, the second conductive part 18′, and the third seed layer 21′. Among them, the first seed layer 15′ and the first conductive part 16′ in the through hole 11 may be collectively referred to as the first conductive component CC1, the first seed layer 15′ and the first conductive part 16′ outside the through hole 11 may be collectively referred to as the first conductive protrusion CP1, the second conductive part 18′ in the through hole 11 may be called the second conductive component CC2, and the second conductive part 18′ outside the through hole 11 may be called the second conductive protrusion CP2, and the third seed layer 21′ may be called the third conductive component CC3.

As shown in FIG. 23, the difference from the substrate structure 1A is that the via CV of the substrate structure 1E further includes the third conductive component CC3. The third conductive component CC3 is disposed in the substrate 10 and penetrates the substrate 10 along the first direction D1, and the third conductive component CC3 surrounds the first conductive component CC1 and the second conductive component CC2. In other words, the third conductive component CC3 is interposed between the inner wall of the substrate 10 and the first conductive component CC1 and the second conductive component CC2. Specifically, the second conductive part 18′ is in direct contact with the first seed layer 15′ to form the first contact interface CI1, and the first conductive part 16′ and the second conductive part 18′ are separated by the first seed layer 15′.

In summary, the present disclosure provides substrate structures and implementations thereof. These substrate structures use release materials as temporary carriers to form vias in stages. In this way, the problem of voids or collapse in the vias may be effectively solved.

The foregoing outlines features of several embodiments of the present disclosure, so that a person of ordinary skill in the art may better understand the aspects of the present disclosure. A person of ordinary skill in the art should appreciate that, the present disclosure may be readily used as a basis for designing or modifying other processes and structures for carrying out the same purposes and/or achieving the same advantages of the embodiments introduced herein. A person of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A substrate structure, comprising:
a substrate having a first surface and a second surface opposite to each other; and
a via disposed in the substrate and penetrating the substrate along a first direction, wherein the via comprises:
a first conductive component adjacent to the first surface of the substrate, wherein the first conductive component comprises a first seed layer and a first conductive part; and
a second conductive component adjacent to the second surface of the substrate and electrically connected to the first conductive component, wherein the second conductive component and the first seed layer form a first contact interface, the first contact interface extends along a second direction, and the second direction is different from the first direction.

2. The substrate structure as claimed in claim 1, wherein the first conductive component has a first sidewall, the second conductive component has a second sidewall, and the first sidewall and the second sidewall form a continuous sidewall.

3. The substrate structure as claimed in claim 1, wherein the second conductive component comprises a second seed layer and a second conductive part, and the second seed layer is in direct contact with the first seed layer to form the first contact interface.

4. The substrate structure as claimed in claim 3, wherein the first conductive part and the second conductive part are separated from each other by the first seed layer and the second seed layer.

5. The substrate structure as claimed in claim 1, wherein the second conductive component comprises a second conductive part, and the second conductive part is in direct contact with the first seed layer to form the first contact interface.

6. The substrate structure as claimed in claim 5, wherein the first conductive part and the second conductive part are separated by the first seed layer.

7. The substrate structure as claimed in claim 5, wherein the first conductive part is in direct contact with the second conductive part to form a second contact interface.

8. The substrate structure as claimed in claim 1, wherein the second conductive component comprises a second seed layer and a second conductive part, and the second seed layer is in direct contact with the first seed layer to form the first contact interface, and the second seed layer is in direct contact with the first conductive part to form a second contact interface.

9. The substrate structure as claimed in claim 1, wherein the via further comprises a third conductive component, the third conductive component is disposed in the substrate and penetrates the substrate along the first direction, and the third conductive component surrounds the first conductive component and the second conductive component.

10. The substrate structure as claimed in claim 9, wherein the second conductive component comprises a second conductive part, and the second conductive part is in direct contact with the first seed layer to form the first contact interface.

11. The substrate structure as claimed in claim 10, wherein the first conductive part and the second conductive part are separated by the first seed layer.

12. The substrate structure as claimed in claim 1, wherein an angle between the first direction and the second direction is greater than 0 degrees and less than 180 degrees.

13. The substrate structure as claimed in claim 12, wherein the first direction and the second direction are perpendicular to each other.

14. The substrate structure as claimed in claim 1, wherein the first conductive component has a first height, the second conductive component has a second height, and a ratio of the first height to the second height is between 1:2 and 2:1.

15. The substrate structure as claimed in claim 14, wherein the first height is the same as the second height.

16. The substrate structure as claimed in claim 1, wherein the first conductive component has a first width, the second conductive component has a second width, and the first width is the same as the second width.

17. The substrate structure as claimed in claim 1, wherein the first contact interface has a curvature greater than 0.

18. The substrate structure as claimed in claim 1, wherein the first conductive component has a first width, and the second conductive component has a second width,
wherein the first width decreases from one side adjacent to the first surface toward one side away from the first surface, or the second width decreases from one side adjacent to the second surface toward one side away from the second surface.

19. The substrate structure as claimed in claim 1, wherein the via further comprises a first conductive protrusion and a second conductive protrusion, wherein the first conductive protrusion is disposed on the first conductive component and protrudes from the first surface of the substrate, and the second conductive protrusion is disposed on the second conductive component and protrudes from the second surface of the substrate.

20. The substrate structure as claimed in claim 19, wherein the first conductive component has a first width, the second conductive component has a second width, the first conductive protrusion has a third width, and the second conductive protrusion has a fourth width, wherein the third width is greater than the first width, and the fourth width is greater than the second width.
